(19) United States
(12) Patent Application Publication
(10) Pub. No.: US 2026/0223702 A1
(43) Pub. Date: Jul. 30, 2026

(54) DIRECT BONDING FOR EMBEDDED BRIDGES WITH VIAS

(71) Applicant: Intel Corporation, Santa Clara, CA (US)

(72) Inventors: Brandon C. MARIN, Gilbert, AZ (US); Robert Alan MAY, Chandler, AZ (US); Minglu LIU, Chandler, AZ (US); Bohan SHAN, Chandler, AZ (US); Jason M. GAMBA, Gilbert, AZ (US); Lilia MAY, Chandler, AZ (US); Tarek A. IBRAHIM, Mesa, AZ (US); Hiroki TANAKA, Gilbert, AZ (US); Srinivas Venkata Ramanuja PIETAMBARAM, Chandler, AZ (US); Jeremy D. ECTON, Gilbert, AZ (US); Gang DUAN, Chandler, AZ (US); Suddhasattwa NAD, Chandler, AZ (US); Benjamin DUONG, Phoenix, AZ (US); Haobo CHEN, Chandler, AZ (US); Xiao LIU, Chandler, AZ (US); Xiyu HU, Phoenix, AZ (US); Wei WEI, Chandler, AZ (US); Bai NIE, Chandler, AZ (US); Ziyin LIN, Chandler, AZ (US); Kyle ARRINGTON, Gilbert, AZ (US); Jose WAIMIN, Gilbert, AZ (US); Ryan CARRAZZONE, Chandler, AZ (US); Hongxia FENG, Chandler, AZ (US); Dingying David XU, Chandler, AZ (US); Bin MU, Tempe, AZ (US); Mohit GUPTA, Chandler, AZ (US); Xiaoying GUO, Chandler, AZ (US); Yiqun BAI, Chandler, AZ (US)

(21) Appl. No.: 19/630,150

(22) Filed: Mar. 26, 2026

Related U.S. Application Data
(63) Continuation of application No. 18/530,059, filed on Dec. 5, 2023.

(51) Int. Cl. H10W 70/65; H10W 20/20; H10W 70/60; H10W 70/63; H10W 70/692; H10W 74/15; H10W 90/00

(52) U.S. Cl. CPC H10W 70/65; H10W 20/20; H10W 70/611; H10W 70/635; H10W 70/692; H10W 90/00; H10W 74/15; H10W 90/722; H10W 90/724; H10W 90/734

(57) ABSTRACT

Embodiments disclosed herein include package substrates with bridge dies. In an embodiment, an apparatus comprises a first layer that is a glass layer. A via is provided through the first layer, where the via is electrically conductive. In an embodiment, a second layer is over the first layer, and the second layer comprises an organic dielectric material. In an embodiment, a cavity is provided in the second layer, where the via is within a footprint of the cavity. In an embodiment, a die is in the cavity. In an embodiment, the die is electrically coupled to the via.

### CROSS-REFERENCE TO RELATED APPLICATIONS

This application is a continuation of U.S. patent application Ser. No. 18/530,059, filed on Dec. 5, 2023, the entire contents of which is hereby incorporated by reference herein.

### BACKGROUND

Computing architectures continue to scale to smaller form factors while pushing towards higher bandwidths and computing capacity. One solution for enabling such design goals is to use chiplet architectures. Instead of a single large chip, a plurality of smaller chiplets are stitched together by a bridge. When the bridge is embedded in the underlying package substrate, the bridge may be referred to as an embedded bridge solution. Existing bridge solutions typically do not allow for power to pass through a thickness of the bridge. Instead, traces are routed over the bridge in order to provide power within the footprint of the bridge. This complicates routing and increases the length of the power delivery path, which can impact performance.

Accordingly, some solutions have proposed the use of bridges that include vias through a thickness of the bridge. This allows for power to pass directly through the bridge and reduces path length and mitigates routing complexity. However, the integration of such bridges into the package substrate is not without issue. One issue that arises is that traditional buildup material has a high thickness variation. This makes it difficult to make proper electrical connections between the bottom of the die and the underlying electrical pads on the package substrate. In order to improve thickness variation issues, some architectures have begun to integrate glass cores into the package substrate. However, as glass cores become more prevalent, concerns with core cracking and other damage are increased. This damage is particularly prevalent when the bridge is close to or directly on the glass core.

### BRIEF DESCRIPTION OF THE DRAWINGS

FIG. 1A is a cross-sectional illustration of a package substrate with an embedded bridge that does not include vias, in accordance with an embodiment.

FIG. 1B is a cross-sectional illustration of a package substrate with an embedded bridge that includes vias, in accordance with an embodiment.

FIG. 2A is a cross-sectional illustration of a package substrate with a cavity in the buildup layers over the glass core, in accordance with an embodiment.

FIG. 2B is a cross-sectional illustration of a package substrate with a cavity and a bridge coupled to the vias in the core by solder, in accordance with an embodiment.

FIG. 2C is a cross-sectional illustration of a package substrate with a cavity and a bridge coupled to the vias in the core by direct copper-to-copper connections, in accordance with an embodiment.

FIGS. 3A-3G are cross-sectional illustrations depicting a process for forming an embedded bridge that is coupled to vias in the core that extend up from a recessed surface, in accordance with an embodiment.

FIG. 4 is a cross-sectional illustration of a package substrate with an embedded bridge that is coupled to the vias in the core by interconnects that pass through a buffer layer, in accordance with an embodiment.

FIG. 5 is a cross-sectional illustration of a package substrate that includes an embedded bridge that is placed in a cavity over a glass layer, in accordance with an embodiment.

FIGS. 6A-6J are cross-sectional illustrations depicting a process for forming an embedded bridge over a glass core in a package substrate, in accordance with an embodiment.

FIG. 7 is a cross-sectional illustration of an electronic system that comprises a package substrate with an embedded bridge that includes vias, in accordance with an embodiment.

FIG. 8 is a schematic of a computing device built in accordance with an embodiment.

### EMBODIMENTS OF THE PRESENT DISCLOSURE

Described herein are electronic systems, and more particularly, architectures for coupling an embedded bridge with vias to an underlying core layer of a package substrate, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, embedded bridge architectures have been used in order to implement device scaling which can lead to smaller devices while maintaining or improving device performance. However, continued scaling of embedded bridge structures has led to greater issues with electrically coupling the bridge to other features within the package substrate.

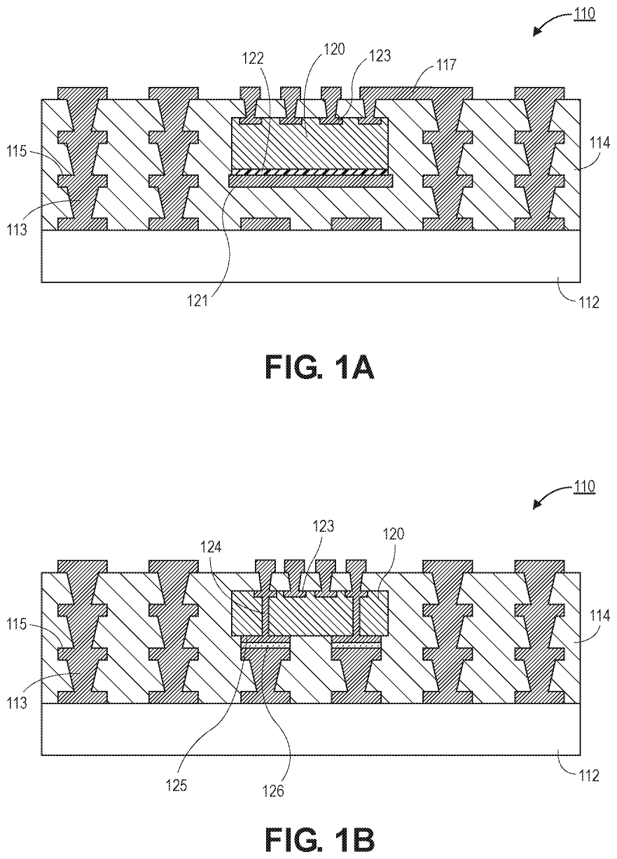

An example of a typical embedded bridge structure is shown in FIG. 1A. In FIG. 1A, a cross-sectional illustration of a package substrate 110 is shown, in accordance with an embodiment. In an embodiment, the package substrate 110 comprises a core 112. The core 112 may be any suitable core material. For example, the core 112 may comprise an organic core with glass fiber reinforcement or the core 112 may comprise a substantially solid glass layer. While shown as a monolithic structure, the core 112 typically includes electrically conductive vias that pass through a thickness of the core 112. In an embodiment, buildup layers 114 may be provided over the core 112. Buildup layers 114 may also be provided over the bottom of the core 112. The bottom portion of the package substrate 110 is omitted from FIG. 1A for clarity since the bridge 120 is located in the top portion of the package substrate 110. The buildup layers 114 may comprise an organic dielectric material. For example, multiple dielectric layers may be laminated over each other in order to form the larger structure of the buildup layers 114. In an embodiment, the buildup layers 114 may comprise electrically conductive routing, such as vias 113, pads 115, traces 117, and the like. The electrically conductive routing may comprise copper, copper alloys, or other metallic materials.

In an embodiment, the bridge 120 is embedded within the buildup layers 114. The bridge 120 may also be referred to as a “die” or a “bridge die” in some embodiments. The bridge 120 may be a dimensionally stable material. For example, the bridge 120 may comprise silicon, other semiconductor materials, a ceramic, glass, or the like. In an embodiment, electrically conductive routing (e.g., traces, pads, etc.) may be provided on the bridge 120. For example, pads 123 are shown in FIG. 1A. In some instances, the routing may be provided in back-end-of-line (BEOL) layers (not shown) over the dimensionally stable base material (e.g., silicon). The BEOL layers may include dielectric materials, such as silicon oxide, silicon nitride, organic dielectrics, and the like. The dimensional stability of the bridge 120 allows for fine line and space (L/S) dimensions in order to provide electrical coupling between overlying dies (not shown in FIG. 1A). In an embodiment, the bridge 120 may be provided over an etchstop layer 121. The etchstop layer 121 may comprise copper or the like. The bridge 120 may be secured to the etchstop layer 121 by an adhesive 122 or the like.

In the illustrated embodiment, there are no vias through a thickness of the bridge 120. Accordingly, power is not able to be routed through the bridge 120. Instead, power is provided in a path that passes adjacent to a sidewall of the bridge 120. Once above the level of the top surface of the bridge 120, a trace 117 can route power into the footprint of the bridge 120. This increases the length of the power delivery path and decreases performance. Additionally, the lateral routing makes routing within the package substrate 110 more complicated.

Accordingly, embodiments disclosed herein may utilize a bridge 120 that includes vias 124. An example of such an embodiment is shown in FIG. 1B. As shown, the vias 124 pass through at least a portion of the thickness of the bridge 120. Pads 125 at the bottom of the bridge 120 are coupled to pads 123 at the top of the bridge 120 through the vias 124. In an embodiment, the bottom pads 125 are coupled to pads 115 in the buildup layers 114 through a solder 126 or the like. In order to make the necessary electrical connections, the thickness variation of the buildup layers 114 needs to be low.

When a glass core 112 is used, thickness variation is typically improved. The improvement is maximized as the bridge 120 is moved closer to the surface of the glass core 112. That is, reducing the thickness of the buildup layers 114 between the bridge 120 and the core 112 is beneficial. However, as the bridge 120 is moved closer to the core 112, potential for damaging the core 112 is increased. The core 112 is brittle and is prone to cracking or other damage. Accordingly, some amount of buffer layer is currently necessary between the core 112 and the bottom of the bridge 120.

Embodiments disclosed herein aim to reduce the distance between the bottom of the bridge 120 and the core 112 without increasing the potential for damage of the core 112. In some embodiments, the bridge 120 is directly coupled to the vias in the core 112. This can be done through either direct bonding (e.g., copper-to-copper bonds) or through the use of a solder. An underfill material may then be provided around the interconnects in order to reduce stresses and mitigate potential damage. In another embodiment, a recess into the core 112 is formed around the vias. The recess can be filled with a dielectric buffer layer in order to reduce stress generation. In yet another embodiment, the bridge can be supported on a glass layer that is embedded within the buildup layers. This provides reduced thickness variation and can allow for the bridge to be moved further from the core 112 in order to reduce stresses on the core 112.

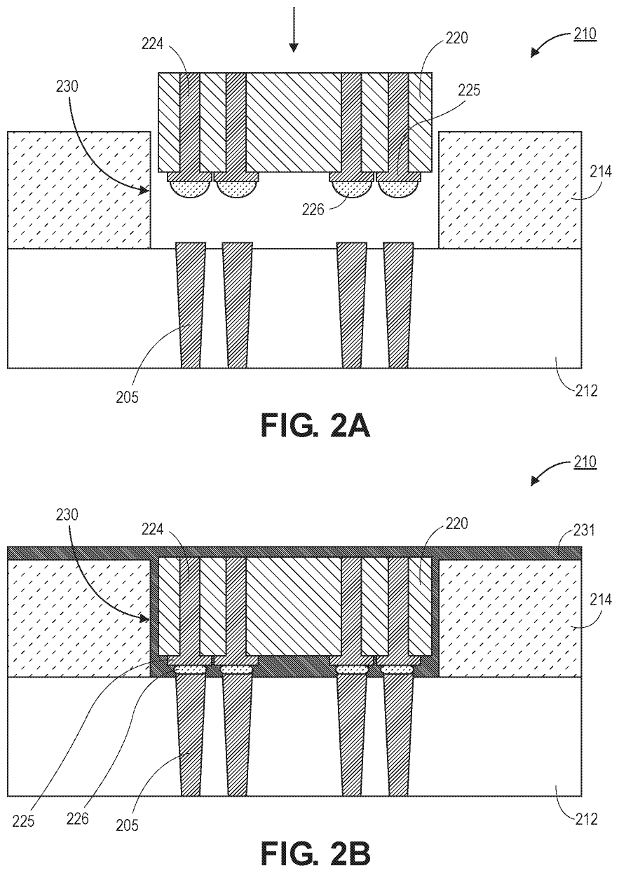

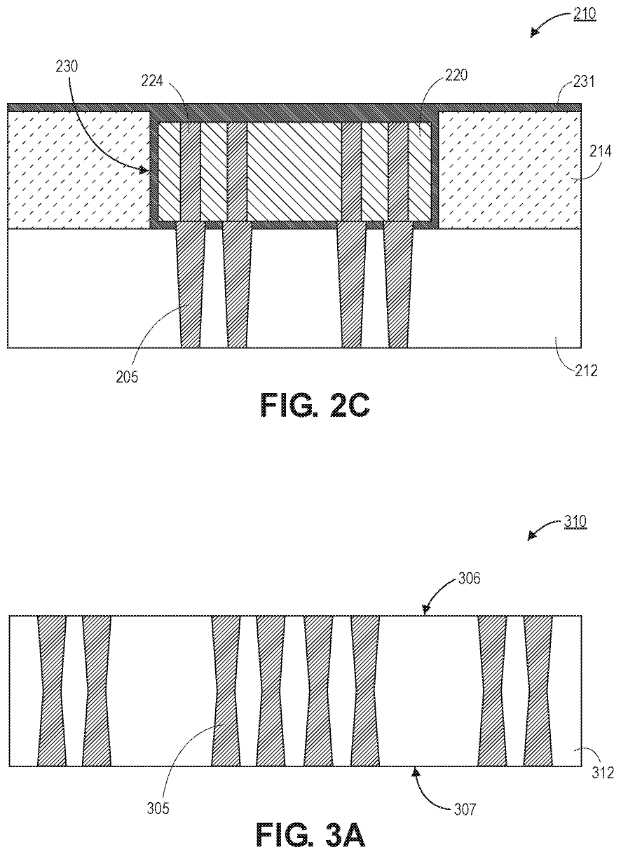

Referring now to FIG. 2A, a cross-sectional illustration of a portion of a package substrate 210 is shown, in accordance with an embodiment. In an embodiment, the package substrate 210 comprises a core 212. The core 212 may comprise glass. The core 212 may be substantially all glass. The core 212 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, core 212 may be distinguished from, for example, the “prepreg” or “RF4” core of a Printed Circuit Board (PCB) substrate which typically comprises glass fibers embedded in a resinous organic material, such as an epoxy.

The core 212 may have any suitable dimensions. In a particular embodiment, the core 212 may have a thickness that is approximately 50 μm or greater. For example, the thickness of the core 212 may be between approximately 50 μm and approximately 1.4 mm. Though, smaller or larger thicknesses may also be used. The core 212 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the core 212 (from an overhead plan view) may be between approximately 10 mm×10 mm and approximately 250 mm×250 mm. In an embodiment, the core 212 may have a first side that is perpendicular or orthogonal to a second side. In a more general embodiment, the core 212 may comprise a rectangular prism volume with sections (e.g., vias) removed and filled with other materials (e.g., metal, etc.).

The core 212 may comprise a single monolithic layer of glass. In other embodiments, the core 212 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the core 212 may each have a thickness less than approximately 50 μm. For example, discrete layers of glass in the core 212 may have thicknesses between approximately 25 μm and approximately 50 μm. Though, discrete layers of glass may have larger or smaller thicknesses in some embodiments.

The core 212 may be any suitable glass formulation that has the necessary mechanical robustness and compatibility with semiconductor packaging manufacturing and assembly processes. For example, the core 212 may comprise aluminosilicate glass, borosilicate glass, alumino-borosilicate glass, silica, fused silica, or the like. In some embodiments, the core 212 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, and Zn. More generally, the core 212 may comprise silicon and oxygen, as well as any one or more of aluminum, boron, magnesium, calcium, barium, tin, sodium, potassium, strontium, phosphorus, zirconium, lithium, titanium, or zinc. In an embodiment, the core 212 may comprise at least 23 percent silicon (by weight) and at least 26 percent oxygen (by weight). In some embodiments, the core 212 may further comprise at least 5 percent aluminum (by weight).

In an embodiment, one or more vias 205 may pass through a thickness of the core 212. The vias 205 may comprise an electrically conductive material, such as copper, an alloy of copper, or any other metallic material. The vias 205 may have substantially vertical sidewalls, or the vias 205 may have tapered or sloped sidewalls. In some instances, the vias 205 may have an hourglass shaped cross-section. In the illustrated embodiment, a portion of the vias 205 may extend past a top surface of the core 212. The vias 205 may also have end surfaces that are substantially coplanar with top and/or bottom surfaces of the core 212.

In an embodiment, buildup layers 214 may be provided over the top surface of the core 212. The buildup layers 214 may comprise an organic dielectric material, such as a buildup film or the like. In an embodiment, individual layers of buildup film may be laminated over each other in order to form the larger structure of the buildup layers 214. In the illustrated embodiment, the buildup layers 214 do not include electrical routing (e.g., pads, traces, vias, etc.) for simplicity. Though, it is to be appreciated that electrical routing can be provided in and/or on the buildup layers 214. In the illustrated embodiment, only top buildup layers 214 are shown over the core 212. However, embodiments may also include buildup layers 214 below the core 212. In an embodiment, the buildup layers 214 are directly contacting the core 212. In other embodiments, a buffer layer (not shown) may be provided between the buildup layers 214 and the core 212. The buffer layer may be a different dielectric material than the buildup layers 214.

In an embodiment, a cavity 230 may be provided through the buildup layers 214. The cavity 230 may pass entirely through a thickness of the buildup layers 214 in order to expose a surface of the core 212. The cavity 230 may have substantially vertical sidewalls, or the sidewalls of the cavity can be sloped. The cavity 230 may be formed with any suitable process, such as laser drilling, etching, or the like.

In an embodiment, a bridge 220 is inserted into the cavity 230, as indicated by the arrow. The bridge 220 may be a semiconductor material, such as silicon or the like. The bridge 220 may include high density electrical routing (not shown) in order to allow for the coupling of overlying dies (not shown) to each other. In an embodiment, vias 224 may pass through at least a portion of the bridge 220. The vias 224 may connect to pads 225 at the bottom of the bridge 220. The pads 225 may include a solder 226 to enable connection to the underlying vias 205. Accordingly, power can be delivered vertically through a thickness of the bridge 220, instead of needing to be routed around the bridge 220 (as is described above).

Referring now to FIG. 2B, a cross-sectional illustration of a package substrate 210 after the bridge 220 is attached to the core 212 is shown, in accordance with an embodiment. In an embodiment, the bridge 220 is coupled to the core 212 through the solder 226 that is provided between the pads 225 and the vias 205. That is, in some embodiments the vias 205 are directly contacted by the solder 226. Though, some instances may include an additional pad between the solder 226 and the via 205. In an embodiment, the remainder of the cavity 230 may be filled with an underfill 231 or the like. The underfill 231 may also extend above a top surface of the buildup layers 214 in some embodiments.

Referring now to FIG. 2C, a cross-sectional illustration of a package substrate 210 is shown, in accordance with an additional embodiment. As shown, the bridge 220 is bonded directly to the vias 205 without a solder. For example, vias 224 are directly bonded to the vias 205. The bond may be a copper-to-copper bond or the like. In some instances, the vias 205 may extend past the top surface of the core 212. When protruding vias 205 are used, an underfill 231 may be used. In other embodiments, the vias 205 may be substantially coplanar with the top surface of the core 212. In such embodiments, the bonding between the bridge 220 and the core 212 may not require an underfill.

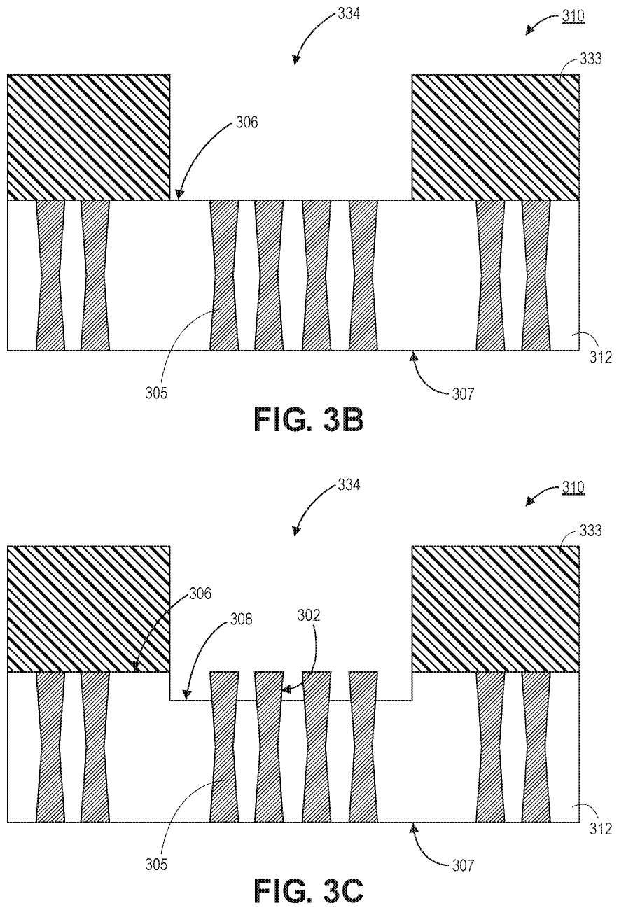

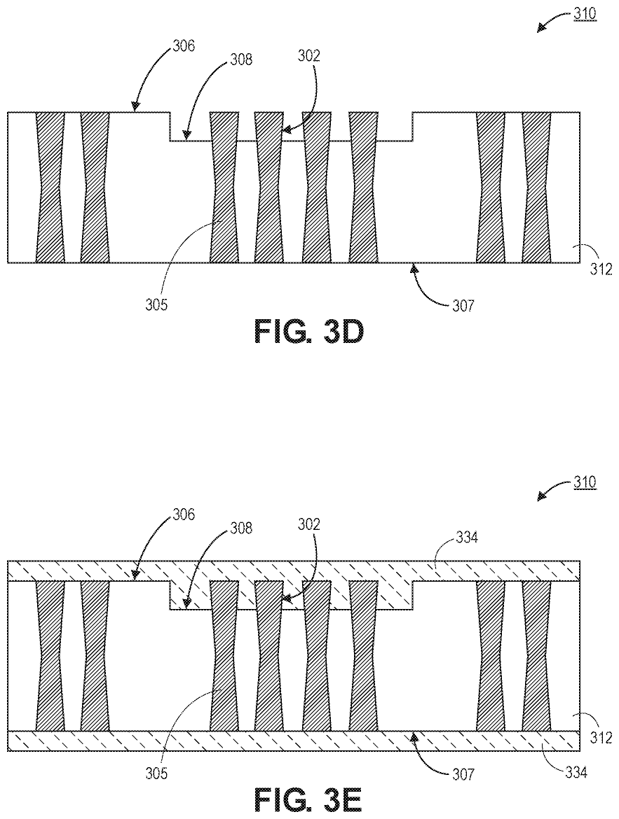

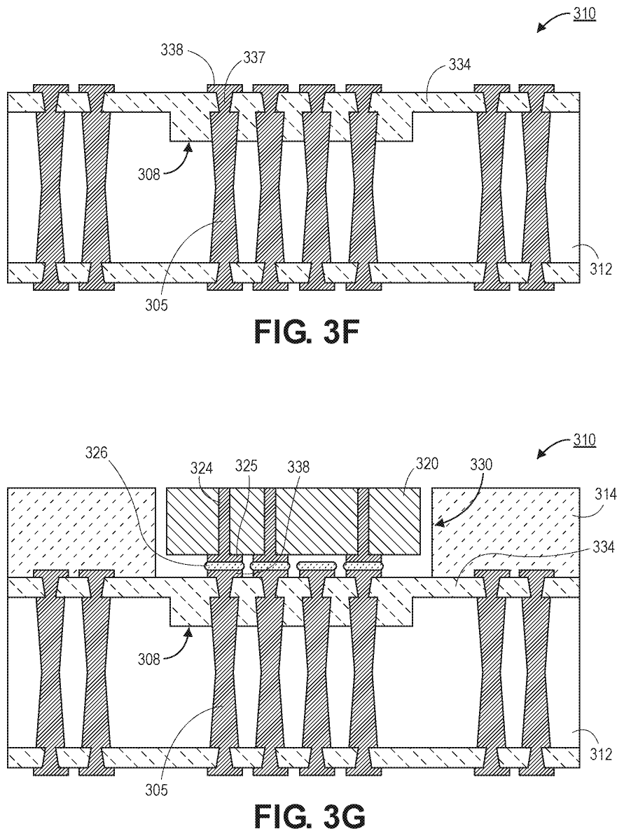

Referring now to FIGS. 3A-3G, a series of cross-sectional illustrations depicting a process for forming a package substrate 310 with a bridge 320 that is close to the core 312 with an intervening buffer layer 334 is shown, in accordance with an embodiment.

Referring now to FIG. 3A, a cross-sectional illustration of a portion of a package substrate 310 is shown, in accordance with an embodiment. In an embodiment, the package substrate 310 may include a core 312, such as a glass core 312 similar to any of the glass cores described in greater detail herein. In an embodiment, the core 312 may comprise one or more vias 305 that pass between a top surface 306 of the core 312 and a bottom surface 307 of the core 312. The vias 305 may have vertical sidewalls, or tapered sidewalls. For example, the vias 305 in FIG. 3A have an hourglass shaped cross-sectional shape.

Referring now to FIG. 3B, a cross-sectional illustration of the package substrate 310 after a resist layer 333 is provided over the top surface 306 is shown, in accordance with an embodiment. The resist layer 333 may be a dry film resist or the like. In an embodiment, an opening 334 is patterned into the resist layer 333. The opening 334 may be provided over one or more vias 305. For example, a group of four vias 305 are within a footprint of the opening 334.

Referring now to FIG. 3C, a cross-sectional illustration of the package substrate 310 after an etching process is shown, in accordance with an embodiment. In an embodiment, the etching process includes etching a portion of the core 312 exposed by the opening 334. The etching process results in a formation of a recessed surface 308 that is provided below (in the Z-direction) the top surface 306. The etching process may be a wet etching process or a dry etching process. In an embodiment, the recess may have a depth up to approximately 20 μm. In some embodiments, the depth of the recess may be between approximately 1 μm and approximately 10 μm. As used herein, “approximately” may refer to a range of values that are within ten percent of the stated value. For example, approximately 10 μm may refer to a range between 9 μm and 11 μm. The recessing process results in a top region 302 of the vias 305 being exposed. The top region 302 may include portions of the sidewalls of the vias 305 as well as the top surfaces of the vias 305.

Referring now to FIG. 3D, a cross-sectional illustration of the package substrate 310 after the resist layer 333 is removed is shown, in accordance with an embodiment. In an embodiment, the resist layer 333 may be removed with a resist stripping process or the like. After the resist layer 333 is removed, the top surface 306 is exposed. Further, the top surface 306 includes a recess 308 that was formed through the etching process described in greater detail above.

Referring now to FIG. 3E, a cross-sectional illustration of the package substrate 310 after a buffer layer 334 is deposited is shown, in accordance with an embodiment. In an embodiment, the buffer layer 334 may be a liquid buildup material or any other suitable dielectric material. After deposition, the buffer layer 334 can be cured. The buffer layer 334 fills the cavity and surrounds the top regions 302 of the vias 305 that extend up from the recessed surface 308. The buffer layer 334 enhances stress reduction of the core 312. Additionally, upon attachment of the bridge 320 in a subsequent operation, the buffer layer 334 absorbs some of the stress and protects the core 312 from cracking or other damage.

Referring now to FIG. 3F, a cross-sectional illustration of the package substrate 310 after vias 337 and pads 338 are formed through and over the buffer layer 334 is shown, in accordance with an embodiment. In an embodiment, the openings for the vias 337 may be formed with a laser ablation process, or the like. Pads 338 and the vias 337 can be plated with any suitable plating and/or patterning process. The vias 337 may land directly on the top surface of the vias 305. That is, in some embodiments, there may not be a pad between vias 337 and vias 305.

Referring now to FIG. 3G, a cross-sectional illustration of the package substrate 310 after buildup layers 314 are added and a bridge 320 is inserted in a cavity 330 in the buildup layers 314 is shown, in accordance with an embodiment. In an embodiment, the buildup layers 314 may be deposited over the buffer layer 334 with a lamination process or the like. The buffer layer 334 may be a different material than the buildup layers 314, or the buildup layers 314 and the buffer layer 334 may be the same material. In some embodiments, the cavity 330 may be formed through the buildup layer 314 with a laser ablation process, an etching process, or the like. The cavity 330 may be provided over the recessed surface 308. That is, the recessed surface 308 may be within a footprint of the cavity 330. Similarly, one or more vias 305 may be within the footprint of the cavity 330.

In an embodiment, the bridge 320 may be coupled to the pads 338 through a solder 326, such as a tin-based solder. In an embodiment, the bridge 320 may comprise bottom pads 325 that may be coupled to vias 324 that extend at least partially through a thickness of the bridge 320. The bridge 320 may be similar to any of the bridge architectures described in greater detail herein. After the bridge 320 is inserted and connected to the core 312, an underfill may be dispensed to fill a remaining volume of the cavity 330. Additional buildup layers can then be provided over the bridge 320.

In an embodiment, positioning the bridge 320 close to the core 312 allows for improved alignment between the bridge pads 325 and the pads 338. This is due, at least in part, to the planarity and thickness uniformity of the core 312. In contrast, existing solutions rely on connecting the bridge 320 over multiple buildup layers 314, which have poor thickness uniformity. As such, manufacturability and yield are improved.

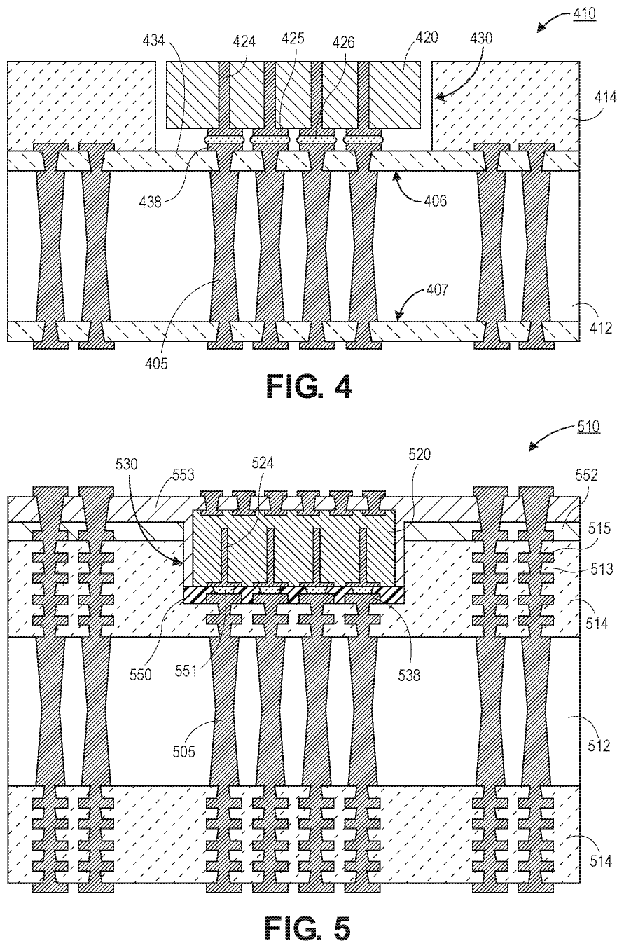

Referring now to FIG. 4, a cross-sectional illustration of a portion of a package substrate 410 is shown, in accordance with an additional embodiment. As shown, the package substrate 410 may include a core 412. The core 412 may be a glass core similar to any of the glass core architectures described in greater detail herein. The core 412 may have a top surface 406 and a bottom surface 407. In an embodiment, vias 405 may pass through a thickness of the core 412. In an embodiment, a buffer layer 434 may be provided over the top surface 406 and/or the bottom surface 407 of the core 412. In contrast to the embodiments shown in FIGS. 3A-3G, the core 412 may not include a recessed surface. As such, the buffer layer 434 may not fill any cavities or surround sidewall portions of the vias 405.

In an embodiment, a cavity 430 may be provided through the buildup layers 414. A bridge 420 is inserted into the cavity 430, and pads 425 of the bridge 420 may be coupled to pads 438 by solder 426 or the like. Vias 424 may be provided through at least a portion of the thickness of the bridge 420. Accordingly, power can be routed from below the bridge 420 up through a thickness of the bridge 420 instead of needing to be routed around a perimeter of the bridge 420.

Referring now to FIG. 5, a cross-sectional illustration of a portion of a package substrate 510 is shown, in accordance with an embodiment. In an embodiment, the package substrate 510 comprises a core 512, such as a glass core 512. In an embodiment, vias 505 may pass through a thickness of the core 512. Buildup layers 514 may be provided above and/or below the core 512. Electrical routing (e.g., pads 515, vias 513, traces, etc.) may be provided in the buildup layers 514. In an embodiment, a solder resist 552 may be provided over the buildup layers 514.

In an embodiment, a cavity 530 may be provided at least partially through a thickness of the solder resist 552 and the buildup layers 514. In an embodiment, a glass layer 550 may be provided at a bottom of the cavity 530. The glass layer 550 may provide a uniform thickness base in order to accurately connect the bridge 520 to the pads 538 underlying the cavity 530. In some embodiments, the pads 538 and solder interconnects 551 may be embedded in or provided over the glass layer 550. Vias 524 may pass at least partially through a thickness of the bridge 520. In an embodiment, an underfill 553 may fill the remainder of the cavity 530 and cover top surfaces of the solder resist 552. Vias may pass through the underfill 553 and connect to pads on the top surface of the underfill 553.

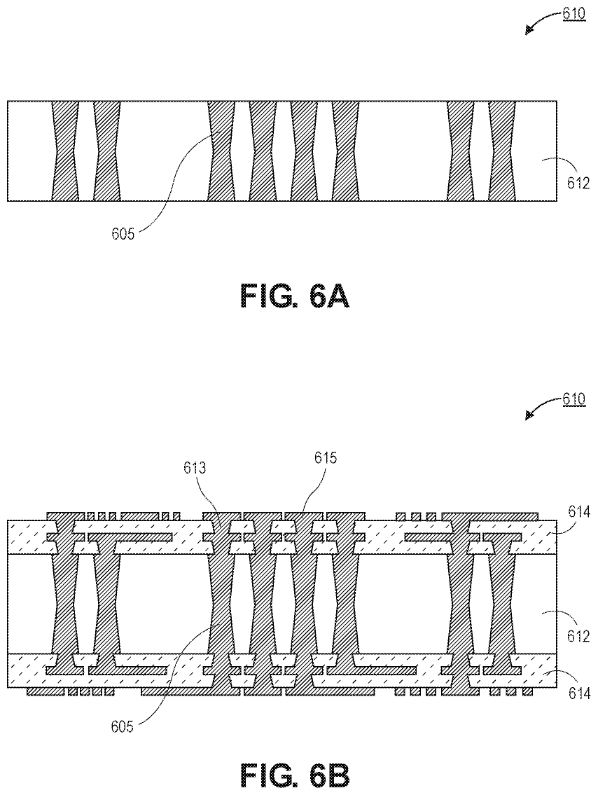

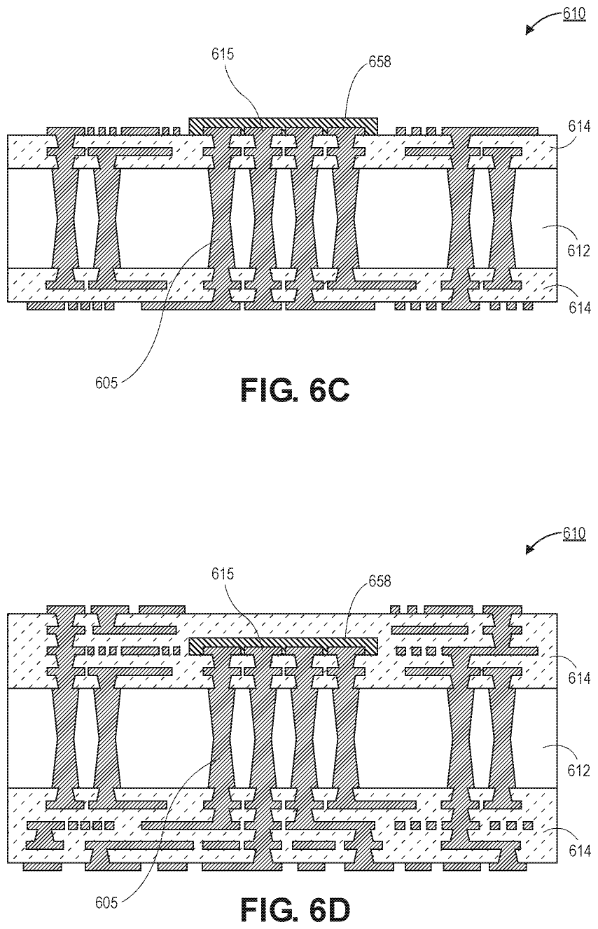

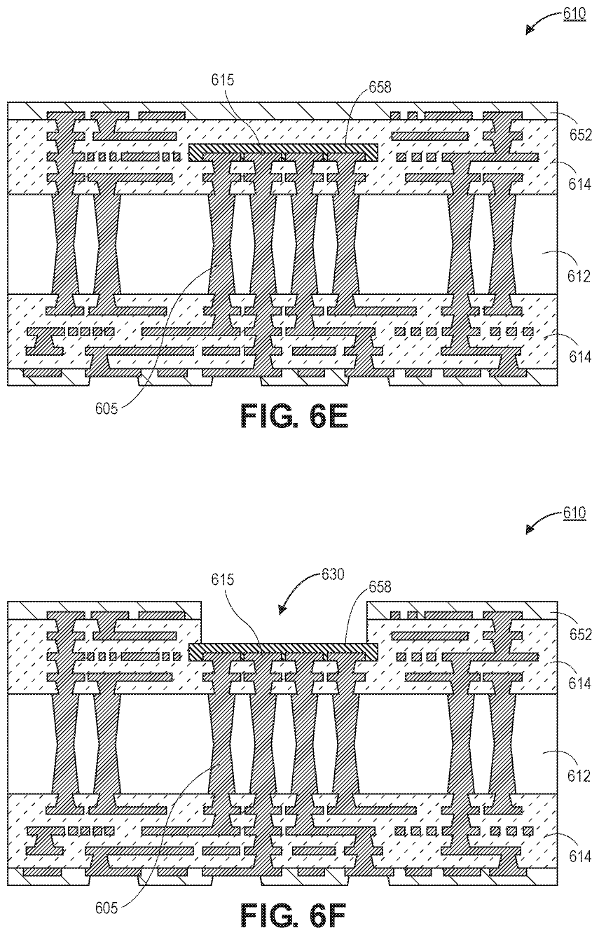

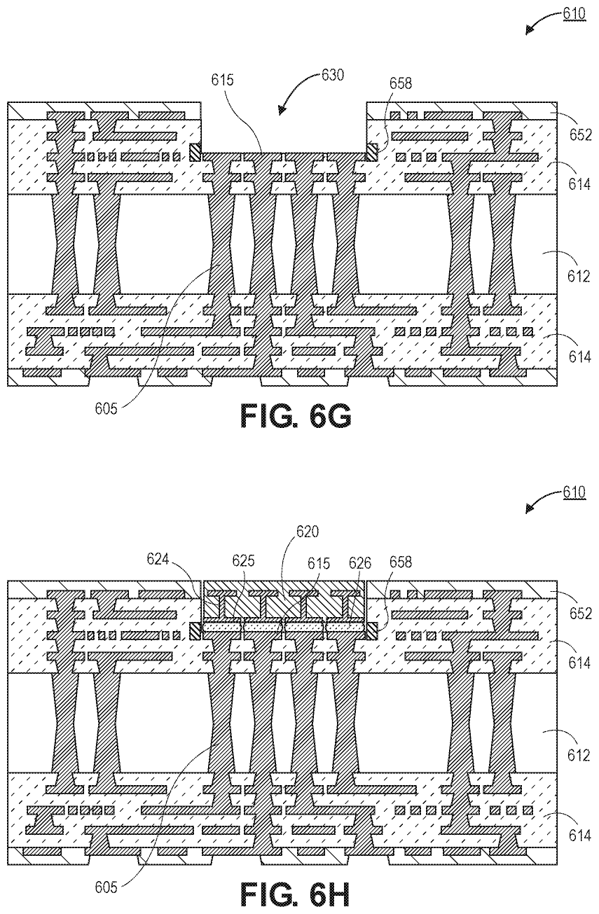

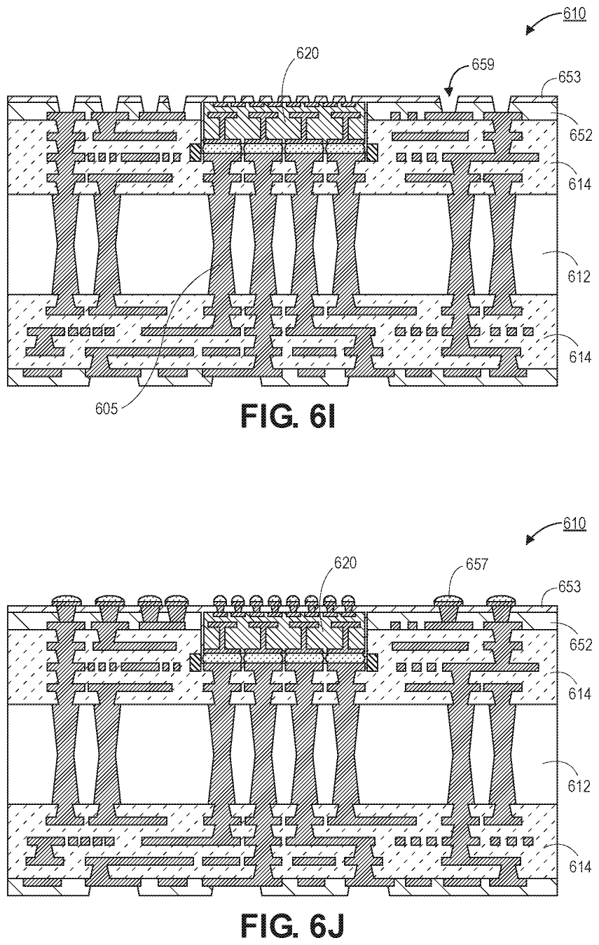

Referring now to FIGS. 6A-6J, a series of cross-sectional illustrations depicting a process for forming a package substrate 610 is shown, in accordance with an embodiment.

Referring now to FIG. 6A, a cross-sectional illustration of a portion of a package substrate 610 is shown, in accordance with an embodiment. In an embodiment, the package substrate 610 comprises a core 612. The core 612 may be a glass core 612 similar to any of the glass core architectures described in greater detail herein. In an embodiment, vias 605 may pass through a thickness of the core 612.

Referring now to FIG. 6B, a cross-sectional illustration of the package substrate 610 after buildup layers 614 are provided above and below the core 612 is shown, in accordance with an embodiment. In an embodiment, the buildup layers 614 may comprise pads 615, vias 613, traces, and the like. The buildup layers 614 and the electrical routing may be formed with typical buildup layer patterning, in accordance with an embodiment.

Referring now to FIG. 6C, a cross-sectional illustration of the package substrate 610 after a pad protection layer 658 is formed over pads 615 is shown, in accordance with an embodiment. In an embodiment, the pad protection layer 658 may be copper or the like. In some instances, an etchstop layer (not shown) may be provided between the pads 615 and the pad protection layer 658 in order to enable easy removal of the pad protection layer 658 in a subsequent operation. For example, the etchstop layer may comprise titanium or the like.

Referring now to FIG. 6D, a cross-sectional illustration of the package substrate 610 after additional buildup layers 614 are provided over the pad protection layer 658 is shown, in accordance with an embodiment. The additional buildup layers 614 may be formed with a lamination process or the like. In some embodiments, the buildup layers 614 may not have any electrical routing above the pad protection layer 658.

Referring now to FIG. 6E, a cross-sectional illustration of the package substrate 610 after a solder resist 652 is provided over the buildup layers 614 is shown, in accordance with an embodiment. The solder resist 652 may be dispensed with a lamination process, or any other suitable deposition process.

Referring now to FIG. 6F, a cross-sectional illustration of the package substrate 610 after a cavity 630 is formed into the buildup layers 614 is shown, in accordance with an embodiment. The cavity 630 may be formed with a laser ablation process, an etching process, or the like. The bottom of the cavity 630 may stop at the pad protection layer 658. In an embodiment, a width of the cavity 630 may be narrower than a width of the pad protection layer 658.

Referring now to FIG. 6G, a cross-sectional illustration of the package substrate 610 after portions of the pad protection layer 658 are removed is shown, in accordance with an embodiment. In an embodiment, the pad protection layer 658 is removed with an etching process. End portions of the pad protection layer 658 outside of the cavity 630 may persist into the final structure of the package substrate 610.

Referring now to FIG. 6H, a cross-sectional illustration of the package substrate 610 after a bridge 620 is inserted into the cavity 630 is shown, in accordance with an embodiment. In an embodiment, pads 625 of the bridge 620 are coupled to pads 615 by solder 626 or the like. The bridge 620 may also comprise vias 624 that pass through at least a portion of the thickness of the bridge 620.

Referring now to FIG. 6I, a cross-sectional illustration of the package substrate 610 after an underfill 653 is provided around the bridge 620 and over the solder resist 652 is shown, in accordance with an embodiment. In an embodiment, the underfill 653 may be a material that is different than the solder resist 652 and/or the buildup layers 614. The underfill 653 may fill a portion of the cavity 630 not occupied by the bridge 620. In an embodiment, via openings 659 may be formed through the underfill 653 and the solder resist 652 with a laser ablation or etching process.

Referring now to FIG. 6J, a cross-sectional illustration of the package substrate 610 after solder 657 is added to the vias and pads in the via openings 659 is shown, in accordance with an embodiment. The solder 657 may be provided with a solder printing process, a plating process, or the like.

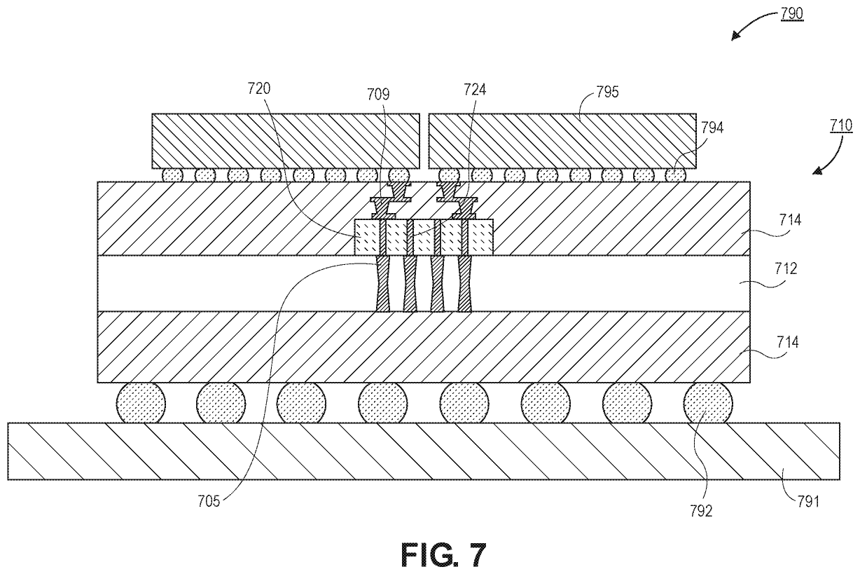

Referring now to FIG. 7, a cross-sectional illustration of an electronic system 790 is shown, in accordance with an embodiment. In an embodiment, the electronic system 790 comprises a board 791, such as a printed circuit board (PCB), a motherboard, or the like. In an embodiment, a package substrate 710 is coupled to the board 791 through interconnects 792. The interconnects 792 may be any suitable second level interconnect (SLI) architecture, such as solder, pins, or the like.

In an embodiment, the package substrate 710 may be similar to any of the package substrate architectures described in greater detail herein. In an embodiment, the package substrate 710 may include a core 712, such as a glass core. Vias 705 may pass through a thickness of the core 712. Buildup layers 714 may be provided above and below the core 712. In an embodiment, a bridge 720 is embedded in the buildup layers 714 above the core 712. The bridge 720 may be similar to any of the bridge architectures described in greater detail herein. For example, vias 724 may pass through at least a portion of a thickness of the bridge 720. In an embodiment, the vias 724 may be coupled to the vias 705. In the illustrated embodiment, a direct copper-to-copper connection is shown. Other embodiments may include pads and/or solder between the vias 724 and the vias 705.

In the illustrated embodiment, the bridge 720 is directly on the core 712. In other embodiments, a buffer layer or a portion of the buildup layers 714 may be provided between the bridge 720 and the core 712. More generally, a first distance between a bottom of the bridge 720 and a top of the core 712 may be smaller than a second distance between a top of the bridge 720 and a top of the buildup layers 714. Moving the bridge 720 closer to the core 712 improves alignment accuracy and makes is more feasible to provide electrical routing (e.g., power) that passes through a thickness of the bridge 720. In an embodiment, routing 709 may couple a top of the bridge 720 to the top of the buildup layers 714.

In an embodiment, the package substrate 710 may be coupled to two or more dies 795 by interconnects 794. The interconnects 794 may include any first level interconnect (FLI) architecture, such as solder, copper bumps, hybrid bonding interfaces, or the like. In an embodiment, the dies 795 may be communicatively coupled to each other through high density routing on the bridge 720. The dies 795 may include a central processing unit (CPU), a graphics processing unit (GPU), an XPU, a communications die, a memory die, or the like.

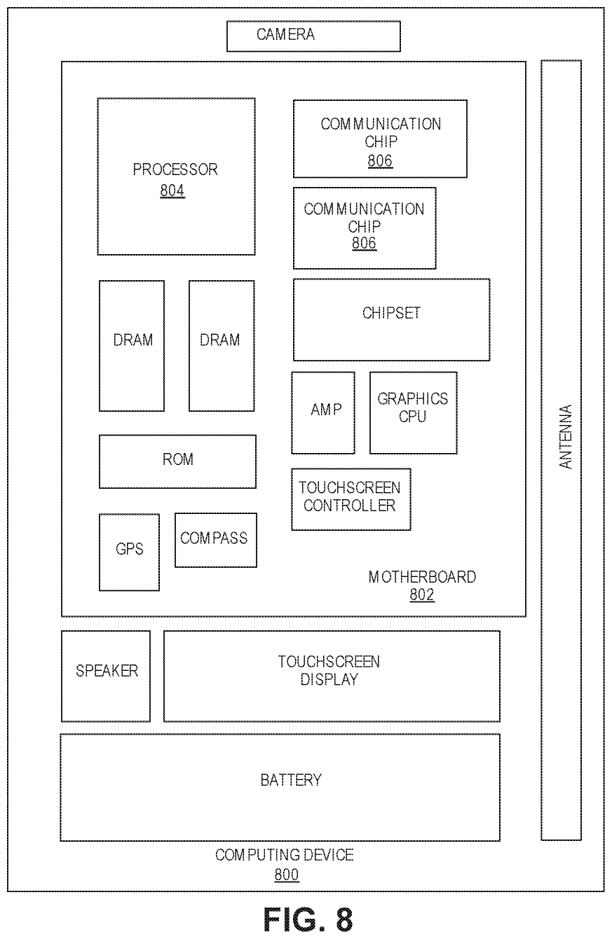

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes a glass core with a bridge that includes vias for vertical power delivery through a thickness of the bridge, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes a glass core with a bridge that includes vias for vertical power delivery through a thickness of the bridge, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a first layer, wherein the first layer is a glass layer; a via through the first layer, wherein the via is electrically conductive; a second layer over the first layer, wherein the second layer comprises an organic dielectric material; a cavity in the second layer, wherein the via is within a footprint of the cavity; and a die in the cavity, wherein the die is electrically coupled to the via.

Example 2: the apparatus of Example 1, wherein a pad is over a bottom surface of the cavity, and wherein the pad is electrically coupled to the via.

Example 3: the apparatus of Example 2, wherein a solder is provided between the pad and the via, or wherein the pad directly contacts the via.

Example 4: the apparatus of Examples 1-3, wherein the first layer comprises a rectangular prism volume.

Example 5: the apparatus of Examples 1-4, further comprising a dielectric layer between the die and the first layer.

Example 6: the apparatus of Examples 1-5, wherein a second via passes through at least a portion of a thickness of the die.

Example 7: the apparatus of Examples 1-6, further comprising: a surface recessed into a top surface of the first layer, wherein the surface is within a footprint of the cavity, and wherein a sidewall of the via is exposed above the surface.

Example 8: the apparatus of Example 7, further comprising: a third layer between the surface and the die, wherein the third layer is a dielectric material.

Example 9: the apparatus of Example 8, wherein a pad over the third layer is electrically coupled to the via, and wherein the die is electrically coupled to the pad.

Example 10: the apparatus of Examples 1-9, wherein the first layer has a thickness in a range from 50 μm to 1.4 mm, a first edge with a first length in a range of 10 mm to 250 mm, and a second edge with a second length in a range of 10 mm to 250 mm, and wherein the first edge is perpendicular to the second edge.

Example 11: an apparatus, comprising: a first layer, wherein the first layer is a glass layer comprising a rectangular prism volume; a via through the first layer, wherein the via is electrically conductive; a second layer over the first layer, wherein the second layer comprises a dielectric material; a cavity partially through a thickness of the second layer, wherein the via is within a footprint of the cavity; a third layer at a bottom of the cavity, wherein the third layer comprises glass; and a die in the cavity, wherein the die is electrically coupled to the via.

Example 12: the apparatus of Example 11, wherein the third layer has a width that is substantially equal to a width of the cavity.

Example 13: the apparatus of Example 11 or Example 12, wherein an opening through the third layer is filled with an electrically conductive material.

Example 14: the apparatus of Examples 11-13, wherein a second via passes through at least a portion of a thickness of the die.

Example 15: the apparatus of Examples 11-14, wherein the die is electrically coupled to the via through one or more second vias that pass through a thickness of the second layer.

Example 16: the apparatus of Examples 11-15, wherein the via has sloped sidewalls.

Example 17: an apparatus, comprising: a board; a package substrate coupled to the board, wherein the package substrate comprises: a core, wherein the core is a glass layer; a first layer over the core with a first surface facing away from the core and a second surface facing the core; a second layer under the core; a bridge embedded in the first layer, wherein a first distance between a bottom surface of the bridge and the second surface of the first layer is smaller than a second distance between a top surface of the bridge and the first surface of the first layer; a first die coupled to the package substrate; and a second die coupled to the package substrate.

Example 18: the apparatus of Example 17, wherein the first die is electrically coupled to the second die by the bridge.

Example 19: the apparatus of Example 17 or Example 18, wherein the bridge comprises a via that passes through at least a portion of a thickness of the bridge.

Example 20: the apparatus of Examples 17-19, wherein the apparatus is part of a personal computer, a server, a mobile device, a tablet, or an automobile.

What is claimed is:

1. An electronic system, comprising:
a first buildup layer having a top side above a bottom side;
a single dielectric layer coupled to the top side of the first buildup layer, the single dielectric layer having first vias passing through a thickness of the single dielectric layer;
a bridge having a bottom directly on a top of the single dielectric layer, the bridge having second vias therein, individual ones of the second vias vertically overlapping with and coupled to corresponding ones of the first vias by a direct copper-to-copper connection;
a second buildup layer over the bridge;
routing coupling the bridge to the second buildup layer;
a graphics processing unit (GPU) die coupled to the routing by first interconnects; and
a memory die coupled to the routing by second interconnects, the memory die laterally spaced apart from the GPU die.

2. The electronic system of claim 1, wherein the single dielectric layer is a glass core.

3. The electronic system of claim 1, wherein the single dielectric layer comprises silicon and oxygen.

4. The electronic system of claim 1, wherein the first vias have tapered sidewalls.

5. The electronic system of claim 1, wherein the first vias couple the second vias to the first buildup layer.

6. The electronic system of claim 1, wherein the GPU die has a top surface at a same level as a top surface of the memory die.

7. The electronic system of claim 1, wherein the GPU die is coupled to the second buildup layer, and wherein the memory die is coupled to the second buildup layer.

8. An electronic system, comprising:
a first buildup layer having a top side above a bottom side;
a single dielectric layer coupled to the top side of the first buildup layer, the single dielectric layer having a first via passing through a thickness of the single dielectric layer;
a bridge having a bottom directly on a top of the single dielectric layer, the bridge having a second via therein, the second via vertically overlapping with and coupled to the first via by a direct copper-to-copper connection;
a second buildup layer over the bridge;
routing coupling the bridge to the second buildup layer;
a graphics processing unit (GPU) die coupled to the second buildup layer by first interconnects; and
a memory die coupled to the second buildup layer by second interconnects, the memory die laterally spaced apart from the GPU die.

9. The electronic system of claim 8, wherein the single dielectric layer is a glass core.

10. The electronic system of claim 8, wherein the first via has tapered sidewalls.

11. The electronic system of claim 8, wherein the first via couples the second via to the first buildup layer.

12. The electronic system of claim 8, wherein the GPU die has a top surface at a same level as a top surface of the memory die.

13. The electronic system of claim 8, wherein the GPU die is coupled to the routing, and wherein the memory die is coupled to the routing.

14. A method of fabricating an electronic system, the method comprising:
forming a first buildup layer having a top side above a bottom side;
forming a single dielectric layer coupled to the top side of the first buildup layer, the single dielectric layer having first vias passing through a thickness of the single dielectric layer;
providing a bridge having a bottom directly on a top of the single dielectric layer, the bridge having second vias therein, individual ones of the second vias vertically overlapping with and coupled to corresponding ones of the first vias by a direct copper-to-copper connection;
forming a second buildup layer over the bridge;
forming routing coupling the bridge to the second buildup layer;
coupling a graphics processing unit (GPU) die to the routing by first interconnects; and
coupling a memory die to the routing by second interconnects, the memory die laterally spaced apart from the GPU die.

15. The method of claim 14, wherein the single dielectric layer is a glass core.

16. The method of claim 14, wherein the single dielectric layer comprises silicon and oxygen.

17. The method of claim 14, wherein the first vias have tapered sidewalls.

18. The method of claim 14, wherein the first vias couple the second vias to the first buildup layer.

19. The method of claim 14, wherein the GPU die has a top surface at a same level as a top surface of the memory die.

20. The method of claim 14, wherein the GPU die is coupled to the second buildup layer, and wherein the memory die is coupled to the second buildup layer.
